(19) United States
(12) Patent Application Publication
(10) Pub. No.: US 2009/0284910 A1
(43) Pub. Date: Nov. 19, 2009

(54) SUPPORTING AND DAMPING STRUCTURE OF HARD DISK DRIVE

(75) Inventors: Baek-ho HEO, Suwon-si (KR); Chul-woo LEE, Seoul (KR)

Correspondence Address: STANZIONE & KIM, LLP, 919 18TH STREET, N.W., SUITE 440, WASHINGTON, DC, 20006, US

(73) Assignee: Samsung Electronics Co., Ltd, Suwon-si (KR)

(21) Appl. No.: 12/465,148

(22) Filed: May 13, 2009

(30) Foreign Application Priority Data
May 14, 2008 (KR) 2008-44719

(51) Int. Cl. H05K 5/02

(52) U.S. Cl. 361/679.36

(57) ABSTRACT

A supporting and damping structure of a hard disk drive (HDD) that includes a housing and a printed circuit board (PCB) coupled to the housing. The supporting and damping structure includes extension parts extending from at least both edges of the PCB beyond the housing; and support members supporting the extension parts so that the HDD does not directly contact an electronic device in which the HDD is installed. The support members include dampers formed of a viscoelastic material and coupled to the extension parts and/or lower supporters and upper supporters respectively disposed on a base and a cover of the electronic device.

### CROSS-REFERENCE TO RELATED APPLICATIONS

This application claims the benefit of Korean Patent Application No. 10-2008-0044719, filed on May 14, 2008, in the Korean Intellectual Property Office, the disclosure of which is incorporated herein in its entirety by reference.

### BACKGROUND OF THE INVENTION

1. Field of the Invention

The present general inventive concept relates to a hard disk drive (HDD), and more particularly, to a structure to support a hard disk drive and to reduce a shock applied to the hard disk drive.

2. Description of the Related Art

Hard disk drives (HDDs) are information storage devices that write data to a disk or read data stored in the disk by using a read/write head. In HDDs, a read/write head is moved to a desired position by an actuator while flying at a predetermined distance away from a recording surface of a rotating disk.

Recently, as the performance of portable electronic devices, such as a portable multimedia player (PMP), a personal digital assistant (PDA), a camcorder, an MP3 player, and a navigator, has been enhanced, the portable electronic devices have been employing a HDD that has a higher information storage capacity. However, the portable electronic devices are required to be light, thin, small, and compact, as well as to have high performance, in order to improve portability. Accordingly, such portable electronic devices typically employ a small form factor HDD that is 1.8, 1.3, 1, or 0.85 inches in diameter.

FIGS. 1A and 1B are a perspective view and a cross-sectional view, respectively, of a supporting and damping structure for a conventional small form factor HDD 10.

Referring to FIGS. 1A and 1B, the conventional small form factor HDD 10 includes a disk, a spindle motor for rotating the disk, a read/write head, and an actuator for moving the read/write head to a desired position on the disk, which are installed in a housing 12 jointly formed by a base member and a cover member. A printed circuit board (PCB) 14 for controlling the spindle motor and the actuator in the housing 12 is coupled by screws to a bottom surface of the housing 12.

The conventional small form factor HDD 10 constructed as described above is installed in an electronic device, e.g., a portable electronic device. A supporting and damping structure for supporting the conventional small form factor HDD 10 in a predetermined space of the electronic device and dampening a shock applied to the electronic device from being delivered to the conventional small form factor HDD 10 is disposed on the conventional small form factor HDD 10. In detail, dampers 20 for supporting the conventional small form factor HDD 10 and reducing a shock delivered to the conventional small form factor HDD 10 are coupled to edges of the conventional small form factor HDD 10. The dampers 20 may be formed of a viscoelastic material, and may have a [symbol] -shaped cross-section so as to be fitted around the edges of the conventional small form factor HDD 10. The dampers 20 have a height H greater than that of the conventional small form factor HDD 10, such that the conventional small form factor HDD 10 does not directly contact the electronic device. As a result, an external shock delivered to the conventional small form factor HDD 10 through the electronic device can be first reduced by the dampers 20.

However, there is a limitation in reducing a shock by making the height H of the dampers 20 greater than that of the conventional small form factor HDD 10, because the electronic device should be compact enough to be portable. Accordingly, if the thickness D of portions 22 of the dampers 20 covering the edges of the conventional small form factor HDD is reduced in order to improve portability, more of an external shock is delivered through the portions 22 to the conventional small form factor HDD 10, thereby failing to obtain satisfactory damping efficiency by the dampers 20. Also, since the dampers 20 are directly coupled to the conventional small form factor HDD 10, a pathway through which a shock is delivered is short.

### SUMMARY OF THE INVENTION

Hard disk drives (HDDs) are information storage devices that write data to a disk or read data stored in the disk by using a read/write head. In HDDs, a read/write head is moved to a desired position by an actuator while flying at a predetermined distance away from a recording surface of a rotating disk.

Additional aspects and utilities of the present general inventive concept will be set forth in part in the description which follows and, in part, will be obvious from the description, or may be learned by practice of the general inventive concept.

The foregoing and/or other aspects and utilities of the present general inventive concept can be achieved by providing a supporting and damping structure of a hard disk drive (HDD) that includes a housing and a printed circuit board (PCB) coupled to the housing, the supporting and damping structure including: extension parts extending from at least both edges of the PCB beyond the housing; and support members supporting the extension parts so that the HDD does not directly contact an electronic device in which the HDD is installed.

The support members may include dampers formed of a viscoelastic material and coupled to the extension parts.

Grooves into which the extension parts are inserted may be formed in the dampers. The dampers may have a height greater than that of the HDD, and have bottom surfaces and top surfaces contacting the electronic device.

The support members may include lower supporters and upper supporters respectively disposed on a base and a cover of the electronic device.

The lower supporters may protrude upward from the base of the electronic device and contact bottom surfaces of the extension parts, and the upper supporters may protrude downward from the cover of the electronic device and contact top surfaces of the extension parts.

The support members may include: dampers formed of a viscoelastic material and coupled to the extension parts; and lower supporters and upper supporters respectively disposed on a base and a cover of the electronic device.

Grooves into which the extension parts are inserted may be formed in the dampers. The dampers may have a height less than that of the HDD. The lower supporters may protrude upward from the base of the electronic device and contact bottom surfaces of the dampers, and the upper supporters may protrude downward from the cover of the electronic device and contact top surfaces of the dampers.

The supporting and damping structure may further include a protective cover coupled to the housing and covering and protecting the PCB. Sidewalls may be formed along edges of the protective cover, and openings through which the extension parts pass may be formed in the sidewalls.

A space may be formed between a top surface of the HDD and the electronic device and between a bottom surface of the HDD and the electronic device, and sponges may be installed in the spaces.

The foregoing and/or other aspects and utilities of the present general inventive concept can also be achieved by providing a HDD assembly, including a base supporting at least one disk and an actuator assembly, a printed circuit board (PCB) to operate the HDD attached at a bottom portion of the base and including extension parts extending from two opposite sides thereof, a casing surrounding and protecting the base and PCB, and a pair of dampers fixed between upper and lower portions of the casing to support a respective one of the extension parts of the PCB such that shocks applied to the casing are absorbed by the dampers before reaching the PCB and the base.

The foregoing and/or other aspects and utilities of the present general inventive concept can also be achieved by providing a HDD assembly, including a damping structure usable with a hard disk drive (HDD) assembly, including first and second damping members, each damping member to support an extension portion of a printed circuit board connected to the HDD assembly, the first and second damping members each having a height greater than the printed circuit board and HDD assembly combination such that shocks applied to a casing of the printed circuit board and HDD assembly combination are absorbed by the first and second damping members before reaching the printed circuit board and HDD assembly combination.

Each of the first and second damping members can include a groove extending along a length thereof to receive the respective extension portion of the PCB therein.

### BRIEF DESCRIPTION OF THE DRAWINGS

The above and other features and utilities of the present general inventive concept will become more apparent by describing in detail exemplary embodiments thereof with reference to the attached drawings in which:

FIGS. 1A and 1B are a perspective view and a cross-sectional view, respectively, of a supporting and damping structure for a conventional small form factor hard disk drive (HDD);

FIG. 2 is an exploded perspective view of a supporting and damping structure of a HDD according to an embodiment of the present general inventive concept;

FIG. 3 is a cross-sectional view of the supporting and damping structure of the HDD of FIG. 2 that is installed in an electronic device;

FIG. 4 is a cross-sectional view of a supporting and damping structure of the HDD of FIG. 2, according to another embodiment of the present general inventive concept; and

FIG. 5 is a cross-sectional view of a supporting and damping structure of the HDD of FIG. 2, according to another embodiment of the present general inventive concept.

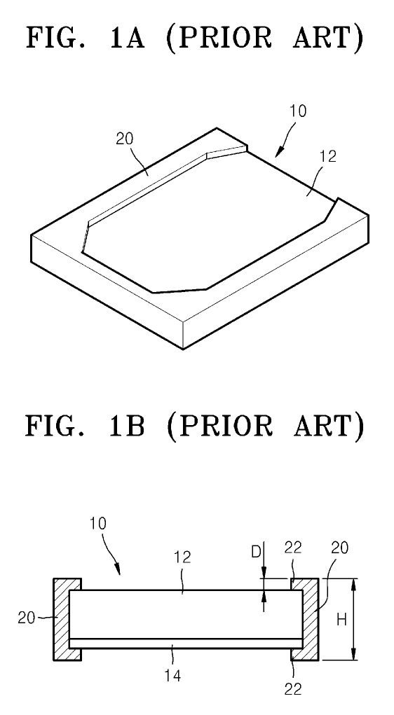

### DETAILED DESCRIPTION OF THE PREFERRED EMBODIMENTS

Reference will now be made in detail to the embodiments of the present general inventive concept, examples of which are illustrated in the accompanying drawings, wherein like reference numerals refer to the like elements throughout. The embodiments are described below in order to explain the present general inventive concept by referring to the figures.

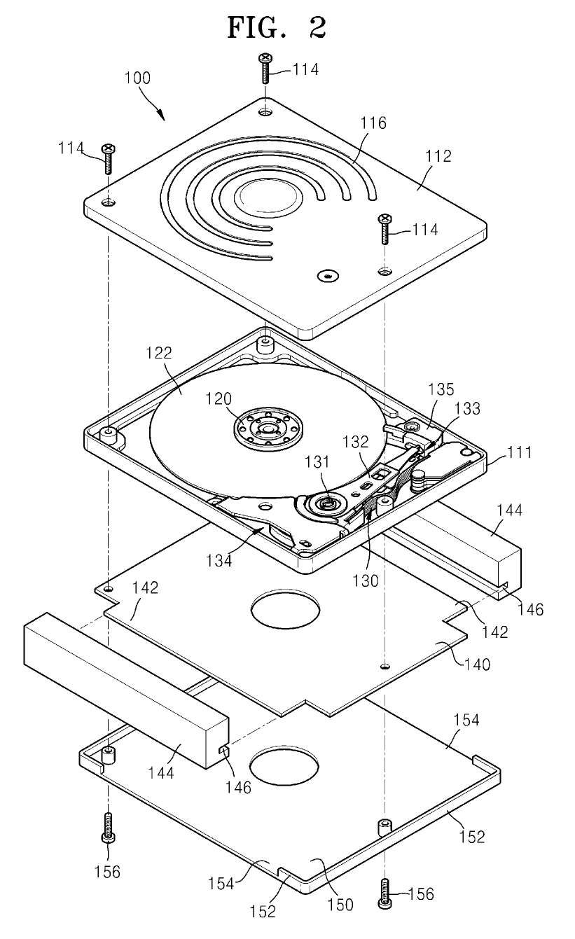

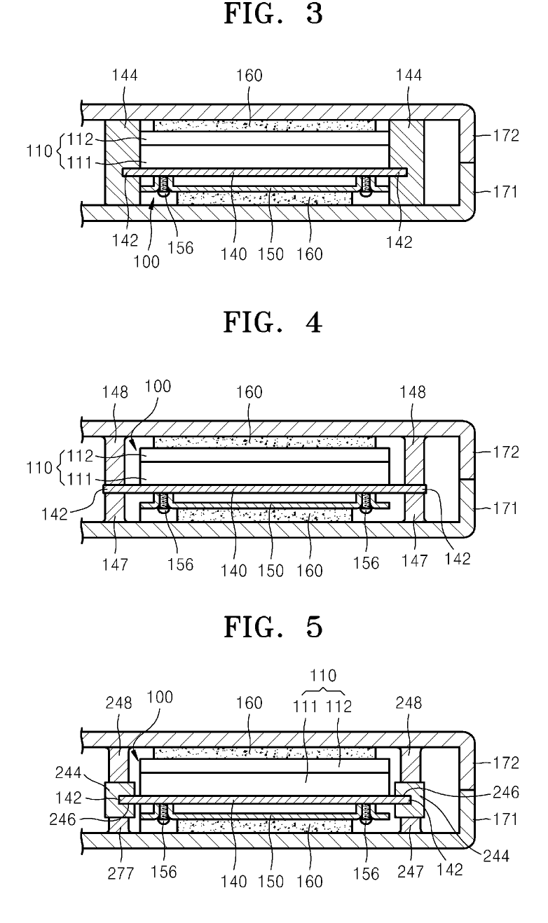

FIG. 2 is an exploded perspective view of a supporting and damping structure of a hard disk drive (HDD) 100 according to an embodiment of the present general inventive concept. FIG. 3 is a cross-sectional view of the supporting and damping structure of the HDD 100 of FIG. 2 that is installed in an electronic device.

Referring to FIGS. 2 and 3, the HDD 100 includes a spindle motor 120, a disk 122 mounted on the spindle motor 120, and an actuator 130 moving a read/write head for reading and writing data to a predetermined position on the disk 122. The actuator 130 includes a swing arm 132 rotatably coupled to an actuator pivot 131, a suspension assembly 133 that is installed on a front end of the swing arm 132 and elastically biases a slider on which the read/write head is mounted toward a surface of the disk 122, and a voice coil motor (VCM) 134 that rotates the swing arm 132.

The VCM 134 is controlled by a servo control system, and rotates the swing arm 132 of the actuator 130 in a direction according to Fleming's left-hand rule due to an interaction between current input to a VCM coil and a magnetic field created by a magnet. That is, if the HDD 100 is turned on and the disk 122 begins to rotate, the VCM 134 rotates the swing arm 132 counterclockwise to move the read/write head to a position above (or adjacent to if situated differently) a recording surface of the disk 122. In contrast, if the HDD 100 is turned off and the disk 122 stops rotating, the VCM 134 rotates the swing arm 132 clockwise to remove the read/write head away from the recording surface of the disk 122. The read/write head moved away from the recording surface of the disk 122 is parked on a parking ramp 135 disposed outside the disk 122.

The spindle motor 120 and the actuator 130 are installed on a base member 111. A cover member 112 is secured to the base member 111 with a plurality of screws 114. The base member 111 and the cover member 112 jointly form a housing 110 surrounding and supporting the disk 122, the spindle motor 120, and the actuator 130. Each of the base member 111 and the cover member 112 is manufactured by pressing a metal plate, preferably, a stainless steel plate. A plurality of reinforcing grooves 116 may be concentrically formed in the cover member 112 in order to strengthen the cover member 112.

A printed circuit board (PCB) 140 is coupled to a bottom surface of the housing 110 to operate the HDD 100. In detail, the PCB 140 is configured such that a plurality of semiconductor chips and circuits are mounted on a non-conductive plastic substrate. The PCB 140 may be protected by a protective cover 150 formed of a metal plate. The protective cover 150 and the PCB 140 may be coupled to the base member 111 of the housing 110 with a plurality of screws 156.

Extension parts 142 extend from edges of the PCB 140 beyond the housing 110. The extension parts 142 may extend from both facing edges among four edges of the PCB 140 as shown in FIG. 2, or may extend from three edges or from all four of the edges of the PCB 140. When sidewalls 152 are formed along edges of the protective cover 150, openings 154 through which the extension parts 142 pass may be formed in the sidewalls 152 in order to prevent the sidewalls 152 of the protective cover 150 from interfering with the extension parts 142.

Dampers 144 may be coupled to the extension parts 142 of the PCB 140 and act as support members supporting the extension parts 142. The dampers 144 may be formed of a viscoelastic material in order to reduce a shock. Grooves 146 into which the extension parts 142 are inserted may be longitudinally formed in the dampers 144 in a longitudinal direction of the extension parts 142. The dampers 144 may have a height greater than that of the HDD 100. Accordingly, when the HDD 100 is installed in an electronic device, e.g., a portable electronic device, a bottom surface and a top surface of each of the dampers 144 contact a base 171 and a cover 172 of the electronic device, respectively, such that the HDD 100 does not directly contact the base 171 and the cover 172 of the electronic device. That is, a predetermined space is formed between the base 171 of the electronic device and the HDD 100 and between the cover 172 of the electronic device and the HDD 100.

In the supporting and damping structure of FIG. 3 constructed as described above, when an external shock is applied to the electronic device, the external shock is not directly delivered to the HDD 100, but is delivered through the base 171 and the cover 172 of the electronic device to the dampers 144 such that the external shock is first reduced by the dampers 144. Next, the external shock is delivered through the extension parts 142 to the PCB 140. The external shock delivered to the PCB 140 may be reduced due to the flexibility of the PCB 140 once more. As described above, since the external shock applied to the electronic device is not directly delivered to the HDD 100, but instead is delivered to the HDD 100 after being reduced by the dampers 144 and the PCB 140, any shock that may finally reach the HDD 100 is much weaker than the initial shock.

As described above, a predetermined space is formed between the protective cover 150 of the HDD 100 and the base 171 of the electronic device and between the cover member 112 of the HDD 100 and the cover 172 of the electronic device. If there is no protective cover 150, a predetermined space is formed between the PCB 140 of the HDD 100 and the base 171 of the electronic device. Sponges 160 may be installed in the spaces. The HDD 100 can be more reliably prevented from directly contacting the base 171 and the cover 172 of the electronic device due to the sponges 160.

FIG. 4 is a cross-sectional view of a supporting and damping structure for the HDD 100 of FIG. 2, according to another embodiment of the present general inventive concept.

Referring to FIG. 4, the extension parts 142 of the PCB 140 may be supported by lower supporters 147 and upper supporters 148 respectively disposed on the base 171 and the cover 172 of the electronic device. The lower supporters 147 may protrude upward from the base 171 of the electronic device, and may have ends contacting bottom surfaces of the extension parts 142. The upper supporters 148 may protrude downward from the cover 172 of the electronic device, and may have ends contacting top surfaces of the extension parts 142. That is, the extension parts 142 of the PCB 140 are inserted between and supported by the lower supporters 147 and the upper supporters 148. The lower supporters 147 have a height high enough for the PCB 140 or the protective cover 150 not to contact the base 171 of the electronic device. The upper supporters 148 have a height high enough for the cover member 112 of the HDD 100 not to contact the cover 172 of the electronic device. Accordingly, a predetermined space is formed between the base 171 of the electronic device and the HDD 100 and between the cover 172 of the electronic device and the HDD 100, and the sponges 160 may be installed in the spaces as described above.

In the supporting and damping structure of FIG. 4 constructed as described above, when an external shock is applied to the electronic device, the external shock is not directly delivered to the HDD 100, but instead is delivered through the extension parts 142 to the PCB 140 such that the external shock is reduced due to the flexibility of the PCB 140. Accordingly, since the external shock applied to the electronic device is delivered to the HDD 100 after being reduced by the PCB 140, any shock eventually reaching the HDD 100 is much weaker than the initial shock.

FIG. 5 is a cross-sectional view of a supporting and damping structure for the HDD 100 of FIG. 2, according to another embodiment of the present general inventive concept.

Referring to FIG. 5, both dampers 244, coupled to the extension parts 142 and lower supporters 247 and upper supporters 248 respectively disposed on the base 171 and the cover 172 of the electronic device, support the extension parts 142 of the PCB 140.

The dampers 244 may be formed of a viscoelastic material in order to reduce any shock. Grooves 246 into which the extension parts 142 are inserted may be longitudinally formed in the dampers 244 in a longitudinal direction of the extension parts 142. The dampers 244 may have a height less than that of the HDD 100.

The lower supporters 247 may protrude upward from the base 171 of the electronic device, and may have ends contacting bottom surfaces of the dampers 244. The upper supporters 248 may protrude downward from the cover 172 of the electronic device, and may have ends contacting top surfaces of the dampers 244. That is, the extension parts 142 of the PCB 140 may be coupled to and supported by the dampers 244 that are inserted between the lower supporters 247 and the upper supporters 248.

The height of each of the dampers 244, the lower supporters 247, and the upper supporters 248 may be determined so that the HDD 100 does not contact the base 171 and the cover 172 of the electronic device. Accordingly, a predetermined space is formed between the base 171 of the electronic device and the HDD 100 and between the cover 172 of the electronic device and the HDD 100, and the sponges 160 may be installed in the spaces.

In the supporting and damping structure of FIG. 5 constructed as described above, when an external shock is applied to the electronic device, the external shock will be first reduced by the dampers 244, and may be reduced again by the PCB 140. Accordingly, since any external shock applied to the electronic device is delivered to the HDD 100 after being reduced or eliminated by the dampers 244 and the PCB 140, any shock eventually reaching the HDD 100 will be much weaker than the initial shock.

As described above, the supporting and damping structure according to the various embodiments of the present general inventive concept can lengthen a pathway through which a shock is delivered by transmitting an external shock applied to the electronic device to the HDD through the flexible PCB, and can improve damping efficiency by sufficiently reducing or eliminating any shock by means of the dampers and the flexible PCB.

While the present general inventive concept has been particularly shown and described with reference to exemplary embodiments thereof, it will be understood by one of ordinary skill in the art that various changes in form and details may be made therein without departing from the spirit and scope of the present general inventive concept as defined by the following claims.

What is claimed is:

1. A supporting and damping structure of a hard disk drive (HDD) that comprises a housing and a printed circuit board (PCB) coupled to the housing, the supporting and damping structure comprising:
extension parts extending from at least both edges of the PCB beyond the housing; and
support members supporting the extension parts so that the HDD does not directly contact an electronic device in which the HDD is installed.

2. The supporting and damping structure of claim 1, wherein the support members comprise dampers formed of a viscoelastic material and coupled to the extension parts.

3. The supporting and damping structure of claim 2, wherein grooves into which the extension parts are inserted are formed in the dampers.

4. The supporting and damping structure of claim 2, wherein the dampers have a height greater than that of the HDD, and have bottom surfaces and top surfaces contacting the electronic device.

5. The supporting and damping structure of claim 1, wherein the support members comprise lower supporters and upper supporters respectively disposed on a base and a cover of the electronic device.

6. The supporting and damping structure of claim 5, wherein the lower supporters protrude upward from the base of the electronic device and contact bottom surfaces of the extension parts, and the upper supporters protrude downward from the cover of the electronic device and contact top surfaces of the extension parts.

7. The supporting and damping structure of claim 1, wherein the support members comprise:
dampers formed of a viscoelastic material and coupled to the extension parts; and
lower supporters and upper supporters respectively disposed on a base and a cover of the electronic device.

8. The supporting and damping structure of claim 7, wherein grooves into which the extension parts are inserted are formed in the dampers.

9. The supporting and damping structure of claim 7, wherein the dampers have a height less than that of the HDD.

10. The supporting and damping structure of claim 7, wherein the lower supporters protrude upward from the base of the electronic device and contact bottom surfaces of the dampers, and the upper supporters protrude downward from the cover of the electronic device and contact top surfaces of the dampers.

11. The supporting and damping structure of claim 1, further comprising a protective cover coupled to the housing and covering and protecting the PCB.

12. The supporting and damping structure of claim 11, wherein sidewalls are formed along edges of the protective cover, and openings through which the extension parts pass are formed in the sidewalls.

13. The supporting and damping structure of claim 1, wherein a space is formed between a top surface of the HDD and the electronic device and between a bottom surface of the HDD and the electronic device, and sponges are installed in the spaces.

14. A HDD assembly, comprising:
a base supporting at least one disk and an actuator assembly;
a printed circuit board (PCB) to operate the HDD attached at a bottom portion of the base and including extension parts extending from two opposite sides thereof;
a casing surrounding and protecting the base and PCB; and
a pair of dampers fixed between upper and lower portions of the casing to support a respective one of the extension parts of the PCB such that shocks applied to the casing are absorbed by the dampers before reaching the PCB and the base.

15. The HDD assembly of claim 14, wherein the dampers include a groove extending along a length of one side thereof to support a respective one of the extension parts of the PCB.

16. The HDD assembly of claim 14, wherein the dampers each include an upper supporter connected to the upper portion of the casing and a lower supporter connected to the lower portion of the casing such that each of the extension parts is supported between an upper and lower supporter of the respective damper.

17. A damping structure usable with a hard disk drive (HDD) assembly, comprising:
first and second damping members, each damping member to support an extension portion of a printed circuit board connected to the HDD assembly, the first and second damping members each having a height greater than the printed circuit board and HDD assembly combination such that shocks applied to a casing of the printed circuit board and HDD assembly combination are absorbed by the first and second damping members before reaching the printed circuit board and HDD assembly combination.

18. The damping structure of claim 17, wherein each of the first and second damping members includes a groove extending along a length thereof to receive the respective extension portion of the PCB therein.
